(19) United States
(12) Patent Application Publication
(10) Pub. No.: US 2025/0390382 A1
(43) Pub. Date: Dec. 25, 2025

(54) ERROR CORRECTION CIRCUIT, STORAGE CONTROLLER INCLUDING ERROR CORRECTION CIRCUIT, AND STORAGE DEVICE INCLUDING STORAGE CONTROLLER

(71) Applicant: SAMSUNG ELECTRONICS CO., LTD., SUWON-SI (KR)

(72) Inventors: KIJUN JEON, Suwon-si (KR); YONGSUNG KIL, Suwon-si (KR); MIN-KI SONG, Suwon-si (KR); DONG-MIN SHIN, Suwon-si (KR); DAE-YEOL YANG, Suwon-si (KR); BOHWAN JUN, Suwon-si (KR); YOUNGJUN HWANG, Suwon-si (KR)

(21) Appl. No.: 18/977,727

(22) Filed: Dec. 11, 2024

(30) Foreign Application Priority Data
Jun. 19, 2024 (KR) 10-2024-0079516

(51) Int. Cl. G06F 11/10

(52) U.S. Cl. CPC G06F 11/1044

(57) ABSTRACT

An error correction circuit includes a first ECC decoder configured to perform a first decoding operation on a codeword including first message data and second message data to generate a plurality of first sign data; a second ECC decoder configured to perform a second decoding operation on the first message data to generate a plurality of second sign data corresponding to the first message data; a first logic circuit bit configured to generate bit flip information indicating a number of times that the first message data and the plurality of second sign data are determined to be different values for each bit; and a second logic circuit configured to modify target sign data and a target reliability data based on the bit flip information, and provide the modified target sign data and the modified target reliability data to the first ECC decoder.

### CROSS-REFERENCE TO RELATED APPLICATION

This patent application claims priority under 35 U.S.C. § 119 to Korean Patent Application No. 10-2024-0079516 filed in the Korean Intellectual Property Office on Jun. 19, 2024, the disclosure of which is incorporated by reference in its entirety herein.

### (a) Technical Field

The present disclosure is directed to an error correction circuit, a storage controller including an error correction circuit, and a storage device including a storage controller.

### (b) Discussion of Related Art

A storage device may include a non-volatile memory device that stores data and a storage controller that controls the non-volatile memory device. Data stored in the non-volatile memory devices may have errors, which are referred to as error bits since they typically occur at the level of individual bits. The storage controller may include an error correction circuit that corrects the error bits included in the data read from the non-volatile memory device. The error correction circuit may include a plurality of Error Correction Code (ECC) decoders that use different error correction codes to increase the ability to correct the error bits included in the data. The plurality of ECC decoders may exchange information related to the data with one another while correcting the error bits included in the data to enhance the effectiveness of the error correction.

### SUMMARY

At least one embodiment provides an error correction circuit that increases the ability to correct error bits included in codewords read from the non-volatile memory device, a storage controller including the error correction circuit, and a storage device including the storage controller.

An error correction circuit according to the present disclosure includes a first ECC decoder configured to perform a first decoding operation on a codeword including first message data and second message data based on a plurality of initial sign data and a plurality of initial reliability data corresponding to the plurality of initial sign data, and generate a plurality of first sign data corresponding to the first message data and a plurality of first reliability data corresponding to the plurality of first sign data; a second ECC decoder configured to perform a second decoding operation on the first message data based on a plurality of first initial sign data corresponding to the first message data among the plurality of initial sign data and a plurality of first initial reliability data corresponding to the plurality of first initial sign data, and generate a plurality of second sign data corresponding to the first message data and a plurality of second reliability data corresponding to the plurality of second sign data; a first logic circuit configured to generate bit flip information indicating number of times that the first message data and the plurality of second sign data are determined to be different values for each bit; and a second logic circuit configured to modify target sign data among the plurality of first initial sign data and target reliability data corresponding to the target sign data based on the bit flip information, and provide the modified target sign data and the modified target reliability data to the first ECC decoder.

A storage controller according to an embodiment includes a memory interface configured to receive a codeword read from a non-volatile memory device; an LLR generator configured to generate initial log likelihood ratios (LLRs) for first message data and second message data included in the codeword; a first ECC decoder configured to perform a first decoding operation based on the initial LLRs to generate first output LLRs; a second ECC decoder configured to perform a second decoding operation based on first initial LLRs corresponding to the first message data among the initial LLRs to generate second output LLRs; a first logic circuit configured to generate bit flip information indicating a number of times that bits included in the first message data are flipped to bits of the plurality of sign data included in the second output LLRs; and a second logic circuit configured to determine a target LLR among the first LLRs based on the bit flip information, modify target sign data of the target LLR based on the bit flip information to generate a modified LLR, and provide the modified LLR to the first ECC decoder.

A storage device according to an embodiment includes a non-volatile memory device configured to store a codeword including first message data, second message data, first parity data, and second parity data; and a storage controller configured to perform a first decoding operation on the first message data and the second message data based on the initial log likelihood ratios (LLRs), perform a second decoding operation on the first message data based on first initial LLRs corresponding to the first message data among the initial LLRs, determine a target LLR among the initial LLRs based on a number of times that bit data included in the first message data is flipped to a different value by the second decoding operation, modify target sign data and target reliability data included in the target LLR based on the number of times, and perform the first decoding operation based on the modified target sign data and the modified target reliability data.

### BRIEF DESCRIPTION OF THE DRAWINGS

FIG. 1 is a view to explain an electronic system including a storage device and host according to an embodiment.

FIG. 2 is a view to explain an error correction circuit according to an embodiment.

FIG. 3 is a view to explain an error correction circuit that performs an encoding operation on a message data received from a host according to an embodiment.

FIG. 4 is a view to explain a threshold voltage distribution of a plurality of memory cells in which codewords are stored according to an embodiment.

FIG. 5 is a view to explain an LLR generator that generates an initial log likelihood ratio (LLR) based on hard decision data and soft decision data according to an embodiment.

FIG. 6 is a view to explain an LLR generator that generates initial LLRs for codewords according to an embodiment.

FIG. 7 is a view to explain an error correction circuit that generates a modified LLR based on a bit flip information according to an embodiment.

FIG. 8 is a view showing a Tanner graph to explain a first decoding operation and a second decoding operation according to an embodiment.

FIG. 9 is a view showing a parity check matrix to explain a first decoding operation and a second decoding operation according to an embodiment.

FIG. 10 is a view to explain a first output LLR and a second output LLR output by a first error correction code (ECC) decoder and a second ECC decoder according to an embodiment.

FIG. 11 is a view to explain a bit flip information generator that generates a bit flip information according to an embodiment.

FIG. 12 is a view to explain a message regenerator that modifies a target LLR based on a bit flip information according to an embodiment.

FIG. 13 is a view to explain an error correction circuit that generates a modified LLR based on the number of repetitions of a first decoding operation and a second decoding operation according to an embodiment.

FIG. 14 is a flowchart to explain an error correction circuit that generates a modified LLR based on a bit flip information according to an embodiment.

FIG. 15 is a view to explain a non-volatile memory device according to an embodiment.

### DETAILED DESCRIPTION

The present disclosure will be described more fully hereinafter with reference to the accompanying drawings, in which exemplary embodiments of the disclosure are shown. The described embodiments may be modified in various different ways, all without departing from the spirit or scope of the present disclosure.

The drawings and description are to be regarded as illustrative in nature and not restrictive. Like reference numerals designate like elements throughout the specification.

In addition, unless explicitly described to the contrary, the word “comprise”, and variations such as “comprises” or “comprising”, will be understood to imply the inclusion of stated elements but not the exclusion of any other elements.

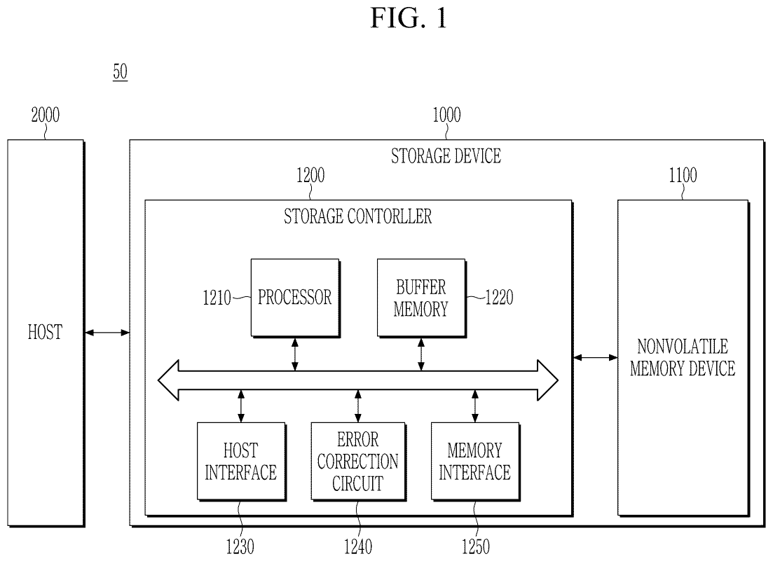

FIG. 1 is a view to explain an electronic system including a storage device and a host according to an embodiment.

Referring to FIG. 1, an electronic system 50 may include a storage device 1000 and a host 2000.

The storage device 1000 may be a device that stores data under the control of the host 2000. In an embodiment, the storage device 1000 may be manufactured in a form of a solid state drive (SSD) or a universal flash storage (UFS).

The storage device 1000 may include a non-volatile memory device 1100 and a storage controller 1200 (e.g., a controller circuit).

The non-volatile memory device 1100 may store data. The non-volatile memory device 1100 may operate in response to the control of the storage controller 1200. In an embodiment, the non-volatile memory device 1100 may be a NAND flash memory. The non-volatile memory device 1100 may include a plurality of memory blocks that store data. Each of the plurality of memory blocks may include a plurality of memory cells. Each memory block may include a plurality of pages, where each page includes a plurality of memory cells.

The non-volatile memory device 1100 may receive a command and an address from the storage controller 1200 and perform an operation indicated by the command for a region selected by the address. The non-volatile memory device 1100 may perform a program operation (a write operation) to store data in a region selected by the address, a read operation to read data, or an erase operation to delete data.

The storage controller 1200 may control the overall operation of the storage device 1000.

In the embodiment, the storage controller 1200 executes firmware when power is applied to the storage device 1000. The firmware may include a host interface layer that controls communication with the host 2000, a flash conversion layer that controls the communication between the host 2000 and the non-volatile memory device 1100, and a memory interface layer that controls communication with the non-volatile memory device 1100. In an embodiment, the flash conversion layer converts a logical address of the host 2000 to a physical address of the non-volatile memory device 1100.

In an embodiment, the storage controller 1200 may control the non-volatile memory device 1100 to perform a write operation, a read operation, or an erase operation according to a request from the host 2000. The storage controller 1200 may provide write commands, addresses, and data to the non-volatile memory device 1100 during the write operation. The storage controller 1200 may provide read commands and addresses to the non-volatile memory device 1100 during the read operation. The storage controller 1200 may provide erase commands and addresses to the non-volatile memory device 1100 during the erase operation.

In an embodiment, the storage controller 1200 include a processor 1210, a buffer memory 1220, a host interface 1230, an error correction circuit 1240, and a memory interface 1250.

The processor 1210 may control the overall operation of the storage controller 1200. The processor 1210 may control the operation of the storage controller 1200 to store data requested from the host 2000 in the non-volatile memory device 1100.

The buffer memory 1220 may be used as a cache memory or an operation memory of the storage controller 1200.

The buffer memory 1220 may temporarily store the data provided from the host 2000 or the data read from the non-volatile memory device 1100. In an embodiment, the buffer memory 1220 may be a dynamic random access memory (DRAM) or a static random access memory (SRAM). While the buffer memory 1220 is illustrated as being positioned inside the storage controller 1200, embodiments of the disclosure are not limited thereto. For example, the buffer memory 1220 may be disposed outside the storage controller 1200.

The host interface 1230 (e.g., an interface circuit) may communicate with the host 2000. The host interface 1230 may receive data from the host 2000 or provide the data to the host 2000.

The error correction circuit 1240 may perform encoding operations and decoding operations. In an embodiment, the error correction circuit 1240 performs an encoding operation to generate parity data for the data received from the host 2000. The encoded data may be provided to the non-volatile memory device 1100 through the memory interface 1250 (e.g., an interface circuit).

In an embodiment, the error correction circuit 1240 performs a decoding operation on data received from the non-volatile memory device 1100. The decoding operation may be an operation that corrects error bits included in the data read from the non-volatile memory device 1100. The error correction circuit 1240 may generate data with the corrected error bits as a result of the decoding operation. The data with the corrected error bits may be provided to the host 2000 through the host interface 1230.

In an embodiment, the error correction circuit 1240 generates initial log likelihood ratios (LLRs) for the data received from the non-volatile memory device 1100. The error correction circuit 1240 may correct the data by performing a first decoding operation and a second decoding operation. The error correction circuit 1240 may perform the second decoding operation to determine a target LLR among the initial LLRs based on a number of times that bit data included in some of the data is flipped with a different value. The error correction circuit 1240 may modify target sign data and target reliability data included in the target LLR to generate a modified LLR including modified target sign data and modified target reliability data. The error correction circuit 1240 may perform the first decoding operation on the data based on the modified LLR to error correct the data.

The memory interface 1250 may communicate with the non-volatile memory device 1100. The memory interface 1250 may provide commands, addresses, and data to the non-volatile memory device 1100. The memory interface 1250 may receive data stored in the non-volatile memory device 1100.

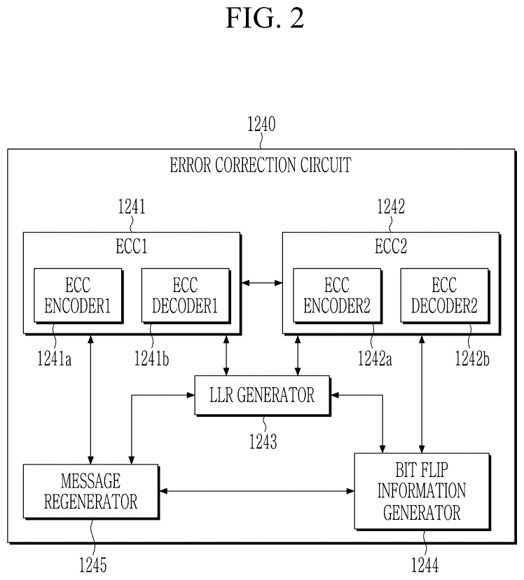

FIG. 2 is a view to explain an error correction circuit according to an embodiment.

Referring to FIG. 2, an error correction circuit 1240 includes a first error correction code (ECC) processing circuit 1241 (ECC1), a second ECC processing circuit 1242 (ECC2), a log likelihood ratio (LLR) generator 1243, a bit flip information generator 1244, and a message regenerator 1245. The log likelihood ratio (LLR) generator 1243, the bit flip information generator 1244, and the message regenerator 1245 may each be implemented by a logic circuit.

In an embodiment, the first ECC processing circuit 1241 includes a first ECC encoder 1241a and a first ECC decoder 1241b. The second ECC processing circuit 1242 may include a second ECC encoder 1242a and a second ECC decoder 1242b. In an embodiment, the first ECC processing circuit 1241 and the second ECC processing circuit 1242 may perform encoding operations and decoding operations by using different error correction codes. In an embodiment, the first ECC processing circuit 1241 performs the encoding operation and the decoding operation by using a low density parity check (LDPC) code, and the second ECC processing circuit 1242 performs the encoding operation and the decoding operation by using a Hamming code.

In the embodiment, the first ECC encoder 1241a performs the first encoding operation on message data received from the host 2000. In an embodiment, the message data includes first message data and second message data. The first ECC encoder 1241a may generate parity data for the message data as a result of performing the first encoding operation.

In the embodiment, the second ECC encoder 1242a performs the second encoding operation on the first message data that is a part of the message data received from the host 2000. The second ECC encoder 1242a generates parity data for the first message data as a result of performing the second encoding operation.

In an embodiment, the first ECC encoder 1241a generates a codeword including the message data, the parity data for the message data, and the parity data for the first message data, and provides the codeword to the non-volatile memory device 1100.

In an embodiment, the LLR generator 1243 generates the initial LLRs based on the codeword read from the non-volatile memory device 1100. The initial LLRs may be a logarithm value for the value that the probability that the value of the bits included in the codeword is “0” is divided by the probability that the value of the bits is “1”. For example, the initial LLRs represent logarithmic values calculated from the ratio of the probability that the bits in the codeword are 0 to the probability that they are 1. The initial LLRs may include initial sign data indicating a sign of the data included in the codeword, and initial reliability data indicating a size of the reliability of the initial sign data. The size may indicate the amount of the confidence in the sign data.

In an embodiment, the first ECC decoder 1241b and the second ECC decoder 1242b perform the first decoding operation and the second decoding operation by using a message passing algorithm.

In an embodiment, the first ECC decoder 1241b performs the first decoding operation on a codeword read from the non-volatile memory device 1100. The first ECC decoder 1241b may correct error bits included in the message data by using the parity data for the message data.

In the embodiment, the first ECC decoder 1241b may input the initial LLRs to variable nodes and check nodes, and modify the initial LLRs according to a message exchange between the variable nodes and the check nodes.

In the embodiment, the first ECC decoder 1241b repeats the first decoding operation to modify the initial LLRs within a maximum number of iterations. In the embodiment, the first ECC decoder 1241b may generate the LLRs corresponding to the first iteration based on the initial LLRs in the first iteration of the first decoding operation. In the embodiment, the first ECC decoder 1241b may generate the LLRs corresponding to the i-th iteration based on the initial LLRs in the i-th iteration (i is a positive integer) of the first decoding operation. The first ECC decoder 1241b may provide the LLRs corresponding to the i-th iteration to the second ECC decoder 1242b.

In an embodiment, the first ECC decoder 1241b determines sign data included in LLRs corresponding to the i-th iteration as hard decision data corresponding to the i-th iteration. The first ECC decoder 1241b may generate syndrome data for the hard decision data corresponding to the i-th iteration by using a parity check matrix. The first ECC decoder 1241b may determine the hard decision data corresponding to the i-th iteration as a valid codeword with the corrected error bits when the syndrome data satisfies constraints of the parity check matrix. In an embodiment, the first ECC decoder 1241b determines the hard decision data corresponding to the i-th iteration as a valid codeword when the values of the bits included in the syndrome data are all “0”. The first ECC decoder 1241b may output the hard decision data corresponding to the i-th iteration as the decoded codeword.

In an embodiment, the first decoding operation fails if the syndrome data that satisfies the constraints of the parity check matrix is not generated within the maximum number of iterations. The failure in the first decoding operation may mean that all error bits included in the codeword have not been corrected.

In an embodiment, the second ECC decoder 1242b performs the second decoding operation on the first message data included in the codeword. The second ECC decoder 1242b may correct the error bits included in the first message data by using the parity data for the first message data.

In the embodiment, the second ECC decoder 1242b repeats the second decoding operation to modify first initial LLRs corresponding to the first message data among the initial LLRs within a maximum number of repetitions. In an embodiment, the second ECC decoder 1242b generates the LLRs corresponding to the k-th iteration (k is a positive integer) of the second decoding operation. The second ECC decoder 1242b may provide the LLRs corresponding to the k-th iteration to the first ECC decoder 1241b.

In the embodiment, the second ECC decoder 1242b may receive the LLRs of the first ECC decoder 1241b corresponding to the i-th iteration of the first decoding operation. The LLRs of the first ECC decoder 1241b may be the LLRs corresponding to the first message data included in the codeword. The second ECC decoder 1242b may modify the LLRs of the second ECC decoder 1242b corresponding to the k-th iteration of the second decoding operation based on the LLRs of the first ECC decoder 1241b. The second ECC decoder 1242b may repeat the second decoding operation for the (k+1)-th time based on modified LLRs according to the LLRs of the first ECC decoder 1241b.

In an embodiment, the first ECC decoder 1241b may receive the LLRs of the second ECC decoder 1242b corresponding to the k-th iteration of the second decoding operation from the second ECC decoder 1242b. The first ECC decoder 1241b may modify the LLRs of the first ECC decoder 1241b corresponding to the i-th iteration of the first decoding operation based on the LLRs of the second ECC decoder 1242b. The first ECC decoder 1241b may repeat the first decoding operation for the (i+1)-th time based on the modified LLRs according to the LLRs of the second ECC decoder 1242b.

In an embodiment, the first ECC decoder 1241b and the second ECC decoder 1242b may increase the ability to correct the error bits of the first message data included in the codeword by exchanging the LLRs corresponding to the i-th and k-th iterations.

In an embodiment, the bit flip information generator 1244 receives the LLRs of the second ECC decoder 1242b corresponding to the k-th iteration of the second decoding operation from the second ECC decoder 1242b. The bit flip information generator 1244 may compare the sign data included in the LLRs of the second ECC decoder 1242b and the sign data included in the first message data, for each bit. The bit flip information generator 1244 may count the number of times that the sign data included in the LLRs of the second ECC decoder 1242b and the sign data included in the first message data are determined to be different values every iteration of the second decoding operation, and generate bit flip information indicating the number of times determined by the different values. The bit flip information generator 1244 may provide the bit flip information to the message regenerator 1245.

In the embodiment, the message regenerator 1245 modifies the first initial LLRs corresponding to the first message data among the initial LLRs based on the bit flip information. In an embodiment, the message regenerator 1245 determines a target LLR among the first initial LLRs based on the bit flip information and modifies the target sign data and the target reliability data included in the target LLR. The message regenerator 1245 may provide the modified LLR including the modified target sign data and the modified target reliability data to the first ECC decoder 1241b.

The first ECC decoder 1241b may modify the target LLR based on the modified LLR. The first ECC decoder 1241b may repeat the first decoding operation by using the modified LLR.

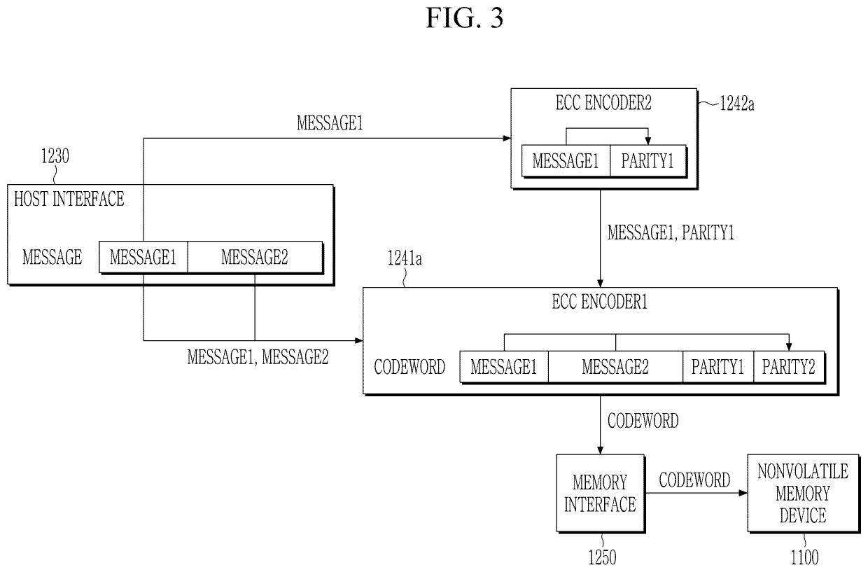

FIG. 3 is a view to explain an error correction circuit that performs an encoding operation on message data received from a host according to an embodiment.

Referring to FIG. 3, a host interface 1230 may receive message data MESSAGE including first message data MESSAGE1 and second message data MESSAGE2 from a host 2000. The host interface 1230 may provide the first message data MESSAGE1 to the second ECC encoder 1242a. The host interface 1230 may provide the first message data MESSAGE1 and the second message data MESSAGE2 to the first ECC encoder 1241a.

In an embodiment, the second ECC encoder 1242a performs the second encoding operation on the first message data MESSAGE1. The second ECC encoder 1242a may generate first parity data PARITY1 for the first message data MESSAGE1 while performing the second encoding operation. The second ECC encoder 1242a may provide the first message data MESSAGE1 and the first parity data PARITY1 to the first ECC encoder 1241a. The second encoding operation performed by the second ECC encoder 1242a may be expressed as Equation 1 according to an embodiment.

$${c}_{{𝒪}_{2}} = {f}_{enc 2} ( {c}_{{𝒥}_{2}} ) \qquad [ Equation 1 ]$$

In Equation 1, [symbol] is the first message data MESSAGE1, f_{enc2}( [symbol] ) is the second encoding operation for the first message data MESSAGE1, and c_{O}_{₂} is the first message data MESSAGE1 and the first parity data PARITY1 output by the second ECC encoder 1242a. The second ECC encoder 1242a may output the first message data MESSAGE1 and the first parity data PARITY1 as a result of performing the second encoding operation on the first message data MESSAGE1.

In an embodiment, the first ECC encoder 1241a receives the first message data MESSAGE1 and the second message data MESSAGE2 from the host interface 1230, and the first message data MESSAGE1 and the first parity data PARITY1 from the second ECC encoder 1242a. The first message data MESSAGE1 received from the host interface 1230 and the first message data MESSAGE1 received from the second ECC encoder 1242a may be the same data.

The first ECC encoder 1241a may perform the first encoding operation for the first message data MESSAGE1 and the second message data MESSAGE2. The first ECC encoder 1241a may generate second parity data PARITY2 for the first message data MESSAGE1 and the second message data MESSAGE2 while performing the first encoding operation. The first encoding operation performed by the first ECC encoder 1241a may be expressed as Equation 2, according to an embodiment.

$${c}_{{𝒪}_{1}} = {f}_{enc 1} ( {c}_{{𝒥}_{1}} ) \qquad [ Equation 2 ]$$

In Equation 2,

$${c}_{{𝒥}_{1}}$$

is the first message data MESSAGE1 and the second message data MESSAGE2, f_{enc1}

$${c}_{{𝒥}_{1}}$$

is the first encoding operation for the first message data MESSAGE1 and the second message data MESSAGE2, and

$${c}_{{𝒪}_{1}}$$

is the first message data MESSAGE1, the second message data MESSAGE2, the first parity data PARITY1, and the second parity data PARITY2 output by the first ECC encoder 1241a. The first ECC encoder 1241a may output the first message data MESSAGE1, the second message data MESSAGE2, the first parity data PARITY1, and the second parity data PARITY2 as a result of performing the first encoding operation.

In an embodiment, the first message data MESSAGE1 may be data double protected by the first parity data PARITY1 and the second parity data PARITY2. The error in the first message data MESSAGE1 may be corrected by the first parity data PARITY1 and the second parity data PARITY2.

In an embodiment, the first ECC encoder 1241a generates a codeword CODEWORD including the first message data MESSAGE1, the second message data MESSAGE2, the first parity data PARITY1, and the second parity data PARITY2. The first ECC encoder 1241a may provide the codeword CODEWORD to the non-volatile memory device 1100 through the memory interface 1250. The non-volatile memory device 1100 may receive the codeword CODEWORD and perform a program operation to store the codeword CODEWORD in the plurality of memory cells.

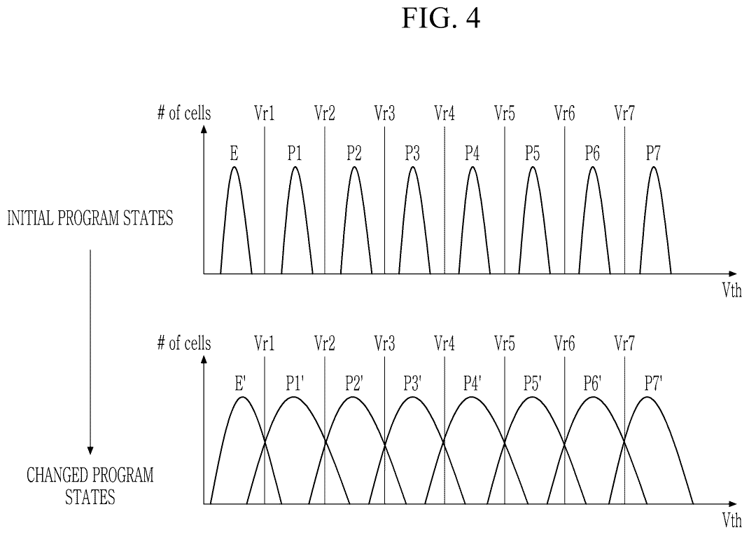

FIG. 4 is a view to explain a threshold voltage distribution of a plurality of memory cells in which codewords are stored according to an embodiment.

In FIG. 4, a horizontal axis of the graph represents a threshold voltage Vth of memory cells, and a vertical axis of the graph represents the number of memory cells (# of cells).

In FIG. 4, an example where one memory cell is programmed as a Triple Level Cell (TLC) that stores three bits of data is described. Referring to FIG. 4, the non-volatile memory device 1100 may perform a program operation to store a codeword in a plurality of memory cells in response to a command from the storage controller 1200.

The plurality of memory cells may be programmed into initial program states INITIAL PROGRAM STATES by a program operation. The threshold voltage of each of the plurality of memory cells may rise to the threshold voltage corresponding to one of an erase state E and the first to seventh program states P1 to P7 while performing the program operation.

In an embodiment, the non-volatile memory device 1100 may perform a read operation to read the codewords stored in the plurality of memory cells by using a plurality of read voltages. The plurality of read voltages may include first to seventh read voltages Vr1 to Vr7. The first to seventh read voltages Vr1 to Vr7 may be voltages used in the read operation for the memory cells corresponding to the erase state E and the first to seventh program states P1 to P7, respectively. In an embodiment, the non-volatile memory device 1100 may read the codewords stored in the memory cells having the threshold voltage corresponding to the seventh program state P7 among the plurality of memory cells by using the seventh read voltage Vr7.

In an embodiment, the threshold voltage of the plurality of memory cells programmed at the initial program states INITIAL PROGRAM STATES may be changed to the threshold voltages corresponding to the program states CHANGED PROGRAM STATES changed over time. In an embodiment, the threshold voltages of the plurality of memory cells programmed in the erase state E, and the first to seventh program states P1 to P7 may be changed into the threshold voltages corresponding to the erase state E′, and the first to seventh program states P1′ to P7′.

In an embodiment, some memory cells among the plurality of memory cells may have the threshold voltages lower than the plurality of read voltages over time. In an embodiment, some of the memory cells programmed initially at the seventh program state P7, which is higher than the seventh read voltage Vr7, may change inadvertently to have a threshold voltage lower than the seventh read voltage Vr7 as a time passes. Since some memory cells inadvertently have the threshold voltages lower than the seventh read voltage Vr7, when the read operation is performed on these memory cells by using the seventh read voltage Vr7, the codewords stored in these memory cells may include error bits.

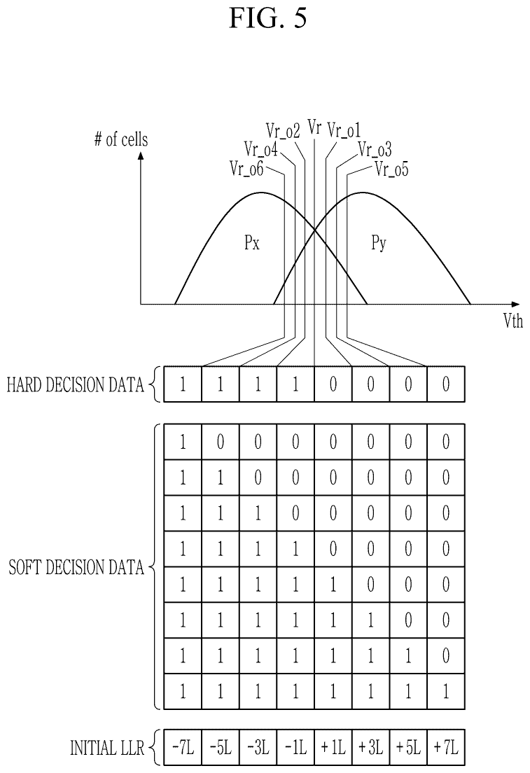

FIG. 5 is a view to explain an LLR generator that generates an initial log likelihood ratio (LLR) based on hard decision data and soft decision data according to an embodiment. For example, the LLR generator may correspond to the LLR generator 1243.

In FIG. 5, a horizontal axis of the graph represents the threshold voltage (Vth) of the memory cells, and a vertical axis of the graph represents the number of memory cells (# of cells). In FIG. 5, Px and Py may be adjacent program states among the plurality of program states. In the embodiment, Px is the third program state P3′ of FIG. 4, and Py is the fourth program state P4′ of FIG. 4.

Referring to FIG. 5, the storage controller 1200 may read the codeword stored in the plurality of memory cells by using a read voltage Vr. In the embodiment, the read voltage Vr may be one of the first to seventh read voltages Vr1 to Vr7 of FIG. 4. In an embodiment, the data read by using the read voltage Vr may be the hard decision data HARD DECISION DATA. In an embodiment, the data stored in the memory cell with the threshold voltage lower than the read voltage Vr among the plurality of memory cells may be read as a data with a bit value of “1”. Among the plurality of memory cells, the data stored in the memory cell with the threshold voltage higher than the read voltage may be read as a data with a bit value of “0”.

The storage controller 1200 may read codewords stored in the plurality of memory cells by using the read voltage Vr and a plurality of offset voltages that have a predetermined size difference from the read voltage Vr. In an embodiment, the plurality of offset voltages include first to sixth offset voltages Vr_o1 to Vr_o6. The data read by using the first to sixth offset voltages Vr_o1 to Vr_o6 may be the soft decision data SOFT DECISION DATA. In an embodiment, the data stored in the memory cell having the threshold voltage higher than the sixth offset voltage Vr_o6 and lower than the fourth offset voltage Vr_o4 among the plurality of memory cells may be read as a data with a bit value of “11000000” by the read voltage Vr and the first to sixth offset voltages Vr_o1 to Vr_o6. In an embodiment, the data stored in the memory cell with the threshold voltage higher than the first offset voltage Vr_o1 and lower than the third offset voltage Vr_o3 among the plurality of memory cells may be read as a data with a bit value of “11111000”.

In an embodiment, the LLR generator 1243 generates initial LLRs INITIAL LLR for the codewords read from the plurality of memory cells based on the hard decision data and/or the soft decision data. In an embodiment, the LLR generator 1243 may determine the initial LLR for the data read from the memory cell with the threshold voltage lower than the sixth offset voltage Vr_o6 as “−7L”. In an embodiment, in “−7L”, “−” may indicate that the bit value is “1”, and “7L” may be the size of the reliability for the bit value “1”. “−7L” may be the initial LLR indicating that the reliability of “1”, which is the bit value of the data read from the memory cell with the threshold voltage lower than the sixth offset voltage Vr_o6, is very high.

In an embodiment, the LLR generator 1243 may determine the initial LLR for the data read from the memory cell with the threshold voltage greater than the sixth offset voltage Vr_o6 and lower than the fourth offset voltage Vr_o4 as “−5L”. “−5L” may be the initial LLR indicating the bit value of “1” with the lower reliability than “−7L”.

In an embodiment, the LLR generator 1243 may determine the initial LLR for the data read from the memory cell with the threshold voltage greater than the fourth offset voltage Vr_o4 and lower than the second offset voltage Vr_o2 as “−3L”. “−3L” may be the initial LLR indicating the bit value of “1” with the lower reliability than “−5L”.

In an embodiment, the LLR generator 1243 may determine the initial LLR for the data read from the memory cell with the threshold voltage greater than the second offset voltage Vr_o2 and lower than the read voltage Vr as “−1L”. “−1L” may be the initial LLR indicating that the bit value is “1” with the lower reliability than “−3L”.

In an embodiment, the LLR generator 1243 may determine the LLR for the data read from the memory cell with the threshold voltage higher than the fifth offset voltage Vr_o5 as “7L”. In “7L”, “+” may indicate that the bit value is “0”, and “7L” may be the size of the reliability for the bit value “0”. “+7L” may be the initial LLR indicating that the reliability of “0”, which is the bit value of the data read from the memory cell with the threshold voltage higher than the fifth offset voltage Vr_o5, is very high.

In the embodiment, the LLR generator 1243 may determine the initial LLR for the data read from the memory cell with the threshold voltage greater than the third offset voltage Vr_o3 and lower than the fifth offset voltage Vr_o5 as “+5L”. “+5L” may be the initial LLR indicating the bit value of “0” with the lower reliability than “+7L”.

In an embodiment, the LLR generator 1243 may determine the initial LLR for the data read from the memory cell with the threshold voltage greater than the first offset voltage Vr_o1 and lower than the third offset voltage Vr_o3 as “+3L”. “+3L” may be the initial LLR indicating the bit value of “0” with the lower reliability than “+5L”.

In an embodiment, the LLR generator 1243 may determine the initial LLR for the data read from the memory cell with the threshold voltage greater than the read voltage Vr and lower than the first offset voltage Vr_o1 as “+1L”. “+1L” may be the initial LLR indicating the bit value of “0” with the lower reliability than “+3L”.

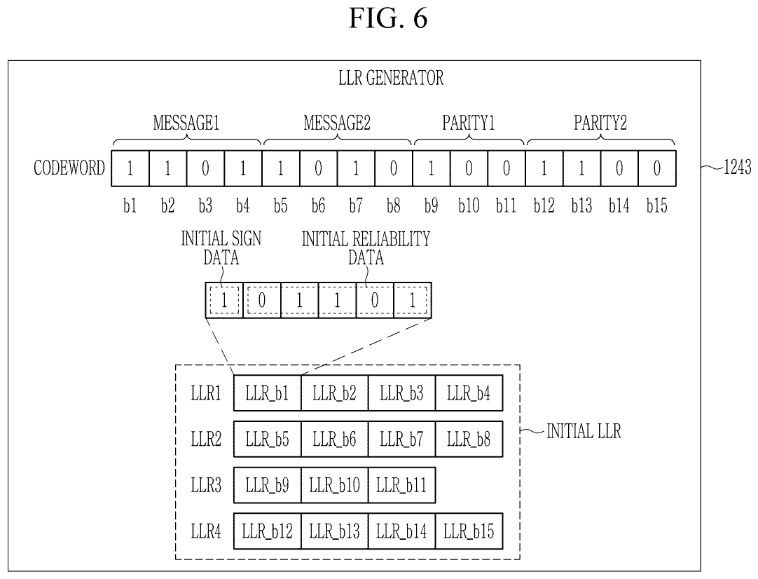

FIG. 6 is a view to explain an LLR generator that generates initial LLRs for codewords according to an embodiment.

Referring to FIG. 6, an LLR generator 1243 may receive the codeword CODEWORD read from the non-volatile memory device 1100. The codeword CODEWORD may include a first message data MESSAGE1, a second message data MESSAGE2, a first parity data PARITY1, and a second parity data PARITY2. The first message data MESSAGE1 may include first to fourth bit data b1 to b4. The second message data MESSAGE2 may include fifth to eighth bit data b5 to b8. The first parity data PARITY1 may include ninth to eleventh bit data b9 to b11. The second parity data PARITY2 may include twelfth to fifteenth bit data b12 to b15. In an embodiment, the codeword CODEWORD may be the hard decision data read by the read voltage Vr.

In an embodiment, the LLR generator 1243 generates initial LLRs INITIAL LLR for the data included in the codeword CODEWORD. In an embodiment, the LLR generator 1243 may generate first initial LLRs LLR1 corresponding to the first message data MESSAGE1, second initial LLRs LLR2 corresponding to the second message data MESSAGE2, third initial LLRs LLR3 corresponding to the first parity data PARITY1, and fourth initial LLRs LLR4 corresponding to the second parity data PARITY2.

In an embodiment, the first initial LLRs LLR1 may include an LLR LLR_b1 corresponding to a first bit of the first message data MESSAGE1, an LLR LLR_b2 corresponding to a second bit of the first message data MESSAGE1, an LLR LLR_b3 corresponding to a third bit of the first message data MESSAGE1, and an LLR LLR_b4 corresponding to a fourth bit of the first message data MESSAGE1.

In an embodiment, the LLR LLR_b1 corresponding to the first bit may include an initial sign data INITIAL SIGN DATA and initial reliability data INITIAL RELIABILITY DATA expressed in six bits. The initial sign data INITIAL SIGN DATA may be data representing the sign of the first bit data b1. The initial sign data INITIAL SIGN DATA may be 1 bit. The bit value of the initial sign data INITIAL SIGN DATA may be the same as the bit value of the first bit data b1. That is, the data included in the codeword CODEWORD may be the initial sign data INITIAL SIGN DATA.

In an embodiment, the initial reliability data INITIAL RELIABILITY DATA is data indicating the size of the reliability for the initial sign data INITIAL SIGN DATA. In an embodiment, the initial reliability data INITIAL RELIABILITY DATA is five bits.

In an embodiment, the LLRs LLR_b2 to LLR_b15 for the second to fifteenth bits may include initial sign data INITIAL SIGN DATA indicating the sign of the second to fifteenth bit data b2 to b15 in the same way as the LLR LLR_b1 for the first bit data and an initial reliability data INITIAL RELIABILITY DATA indicating the size of the reliability of the initial sign data, respectively.

In an embodiment, the initial LLRs INITIAL LLR may include a plurality of initial sign data and a plurality of initial reliability data. The first initial LLRs LLR1 may include a plurality of first initial sign data and a plurality of first initial reliability data. The second initial LLRs LLR2 may include a plurality of second initial sign data and a plurality of second initial reliability data. The third initial LLRs LLR3 may include a plurality of third initial sign data and a plurality of third initial reliability data. The fourth initial LLRs LLR4 may include a plurality of fourth initial sign data and a plurality of fourth initial reliability data.

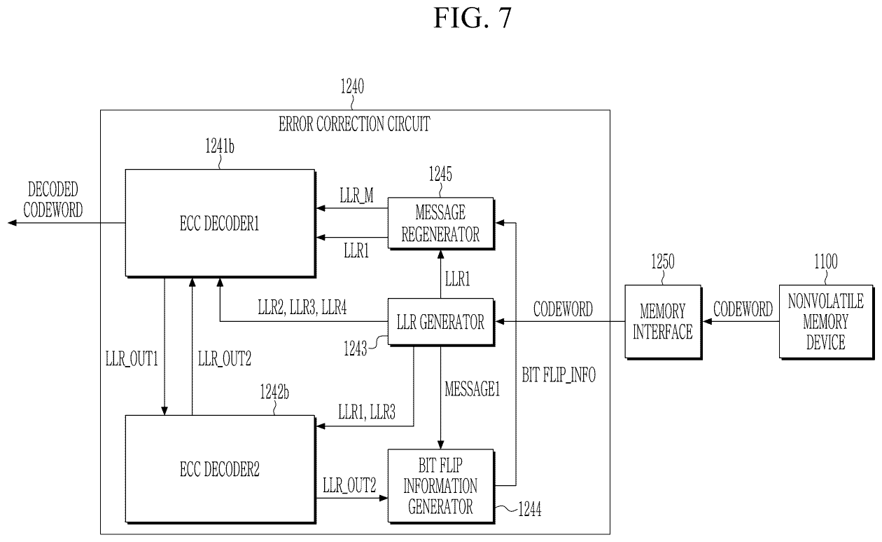

FIG. 7 is a view to explain an error correction circuit that generates a modified LLR based on a bit flip information according to an embodiment.

Referring to FIG. 7, an LLR generator 1243 may receive a codeword CODEWORD read from a non-volatile memory device 1100 through a memory interface 1250 and generate initial LLRs based on the codeword CODEWORD. The initial LLRs may include first initial LLRs LLR1 corresponding to a first message data, second initial LLRs LLR2 corresponding to a second message data, third initial LLRs LLR3 corresponding to a first parity data, and fourth initial LLRs LLR4 corresponding to a second parity data. The LLR generator 1243 may provide the first initial LLRs LLR1 to the first ECC decoder 1241b through the message regenerator 1245, and the second to fourth initial LLRs LLR2 to LLR4 to the first ECC decoder 1241b. The LLR generator 1243 may provide the first initial LLRs LLR1 and the third initial LLRs LLR3 to a second ECC decoder 1242b. The LLR generator 1243 may provide first message data MESSAGE1 included in the codeword CODEWORD to a bit flip information generator 1244.

In an embodiment, the first ECC decoder 1241b may modify the first to fourth initial LLRs LLR1 to LLR4 by repeating the first decoding operation. The first ECC decoder 1241b may generate the LLRs of the first ECC decoder 1241b corresponding to the i-th iteration of the first decoding operation. The first ECC decoder 1241b may generate the LLRs corresponding to the first message data, the LLRs corresponding to the second message data, and the LLRs corresponding to the first parity data, and the LLRs corresponding to the second parity data in the i-th iteration of the first decoding operation.

In an embodiment, the first ECC decoder 1241b may generate a first output LLR LLR_OUT1 based on the LLRs corresponding to the first message data among the LLRs corresponding to the i-th iteration of the first decoding operation and provide the first output LLR LLR_OUT1 to the second ECC decoder 1242b. The first output LLR LLR_OUT1 may include a plurality of first sign data representing the sign of the LLRs of the first ECC decoder 1241b corresponding to the i-th iteration of the first decoding operation and a plurality of first reliability data representing the size of the reliability of the plurality of first sign data.

In an embodiment, the second ECC decoder 1242b may repeat the second decoding operation to modify the first initial LLRs LLR1 and the third initial LLRs LLR3. In an embodiment, the second ECC decoder 1242b may perform the second decoding operation based on the first initial LLRs LLR1 and the third initial LLRs LLR3 received from the LLR generator 1243 and the first output LLR LLR_OUT1 received from the first ECC decoder 1241b

The LLRs used in the second decoding operation may be expressed as Equation 3, according to an embodiment.

$${L}_{j}^{DEC \_ in \_ 2} = {L}_{j}^{ch} + {L}_{j}^{OUT \_ 1} , where {L}_{j}^{OUT \_ 1} = {\tilde{L}}_{j}^{DEC \_ out \_ 1} \qquad [ Equation 3 ]$$

In Equation 3,

$${L}_{j}^{ch}$$

is the initial LLR corresponding to the j-th bit among the bits included in the codeword,

$${L}_{j}^{OUT \_ 1}$$

is the first output LLR LLR_OUT1 and

$${L}_{j}^{DEC \_ in \_ 2}$$

are the LLRs received from the second ECC decoder 1242b, which may include the initial LLR and the first output LLR LLR_OUT1. In an embodiment,

$${\tilde{L}}_{j}^{DEC \_ out \_ 1}$$

is the LLR that the LLRs corresponding to the i-th iteration of the first decoding operation are quantized by the number of specific bits. In an embodiment,

$${\tilde{L}}_{j}^{DEC \_ out \_ 1}$$

is the LLR representing the LLRs corresponding to the i-th iteration of the first decoding operation expressed into 3 bits. The first ECC decoder 1241b may provide the LLRs that the LLRs corresponding to the i-th iteration are quantized into 3 bits to the second ECC decoder 1242b as the first output LLR LLR_OUT1.

In an embodiment, the second ECC decoder 1242b generates LLRs of the second ECC decoder 1242b corresponding to the k-th iteration of the second decoding operation. The second ECC decoder 1242b may generate a second output LLR LLR_OUT2 based on the LLRs of the second ECC decoder 1242b corresponding to the k-th iteration and provide the second output LLR LLR_OUT2 to the first ECC decoder 1241b and the bit flip information generator 1244. In an embodiment, the second output LLR LLR_OUT2 may include a plurality of second sign data indicating signs of the LLRs corresponding to the k-th iteration of the second decoding operation and a plurality of second reliability data indicating the size of the reliability of the second sign data.

The first ECC decoder 1241b may perform the first decoding operation based on the first to fourth initial LLRs LLR1 to LLR4 and the second output LLR LLR_OUT2. The LLRs used in the first decoding operation may be represented by Equation 4, according to an embodiment.

$${L}_{j}^{DEC \_ in \_ 1} = {L}_{j}^{ch} + {L}_{j}^{OUT \_ 2} , where {L}_{j}^{OUT \_ 2} = \{ \begin{matrix}0 , if j ∈ {𝒥}_{s} , \\ {\tilde{L}}_{j}^{DEC \_ out \_ 2} , otherwise ,\end{matrix} \qquad [ Equation 4 ]$$

In an equation 4,

$${L}_{j}^{ch}$$

is the initial LLR corresponding to the j-th bit among the bits included in the codeword,

$${L}_{j}^{OUT \_ 2}$$

is the second output LLR LLR_OUT2 and

$${L}_{j}^{DEC \_ in \_ 1}$$

are the LLRs received from the first ECC decoder 1241b and include the initial LLR and the second output LLR LLR_OUT2. If the j-th bit is the bit included in the second message data, the second output LLR may be 0.

$${\tilde{L}}_{j}^{DEC \_ out \_ 2}$$

may be the LLR that the LLRs corresponding to the k-th iteration of the second decoding operation are quantized by the number of specific bits. In an embodiment,

$${\tilde{L}}_{j}^{DEC \_ out \_ 2}$$

may be the LLRs that the LLRs corresponding to the k-th iteration of the second decoding operation are expressed into 3 bits. The second ECC decoder 1242b may provide the LLRs that the LLRs corresponding to the k-th iteration are quantized into 3 bits to the first ECC decoder 1241b as the second output LLR.

In an embodiment, the bit flip information generator 1244 receives the second output LLR LLR_OUT2 for each repetition of the second decoding operation and receives the first message data MESSAGE1 from the LLR generator 1243.

In the embodiment, the bit flip information generator 1244 compares the plurality of second sign data included in the second output LLR LLR_OUT2 and the first message data MESSAGE1, for each bit. The bit flip information generator 1244 may count the number of times that the bit data included in the second sign data and the first message data MESSAGE1 is determined as a different value for each repetition of the second decoding operation, and generate bit flip information BIT FLIP_INFO indicating the number of times that it is determined as the different value. The bit flip information BIT FLIP_INFO may include information about the count times for each bit data included in the first message data MESSAGE1. The bit flip information generator 1244 may provide the bit flip information BIT FLIP_INFO to the message regenerator 1245.

In an embodiment, the message regenerator 1245 determines a target LLR among the first initial LLRs LLR1 corresponding to the first message data MESSAGE1 based on the bit flip information BIT FLIP_INFO, and modifies target sign data and target reliability data included in the target LLR. In an embodiment, the message regenerator 1245, based on the bit flip information BIT FLIP_INFO, may determine the LLR including the initial sign data where the number of times determined as a different value is greater than a predetermined number of times among the initial sign data included in the first initial LLRs LLR1 as the target LLR. For example, the message regenerator 1245 may identify the LLR with initial sign data, where the number of times it differs from the bit flip information BIT FLIP_INFO exceeds a predetermined threshold, as the target LLR among the initial sign data included in the first initial LLRs LLR1.

In an embodiment, the message regenerator 1245 modifies the target sign data and the target reliability data based on the bit flip information BIT FLIP_INFO and the target reliability data indicating the size of the reliability of the target sign data included in the target LLR. In an embodiment, the message regenerator 1245 modifies the target sign data and the target reliability data if the number of times that the target sign data is determined as a different value is greater than a predetermined number of times, and the size of the reliability of the target sign data is greater than a predetermined size. The message regenerator 1245 may provide the modified LLR LLR_M including the modified target sign data and the modified target reliability data to the first ECC decoder 1241b. The modified LLR LLR_M may be expressed as Equation 5, according to an embodiment.

$${\tilde{L}}_{j}^{ch} = θ ( {L}_{j}^{ch} , {s}_{j} ) , for j ∈ {𝒥}_{d} \qquad [ Equation 5 ]$$

In Equation 5,

$${\tilde{L}}_{j}^{ch}$$

is the modified LLR LLK_M corresponding to the j-th bit among the bits included in the codeword,

$${L}_{j}^{ch}$$

is the initial LLR corresponding to the j-th bit among the bits included in the codeword and s; is the bit flip information corresponding to the j-th bit among the bits included in the codeword. In Equation 5,

$$θ ( {L}_{j}^{ch} , {s}_{j} )$$

may be a non-linear function that determines the size of the reliability of the modified sign value indicated by the modified target sign data of the modified LLR and the modified sign value indicated by the modified target reliability data based on the initial LLR corresponding to the j-th bit and the bit flip information corresponding to the j-th bit.

If the j-th bit is the bit included in the first message data MESSAGE1, the size of the reliability of the sign value indicated by the modified target sign data of the modified LLR and the sign value indicated by the modified target reliability data may be determined.

In an embodiment, the first ECC decoder 1241b modifies the target LLR based on the modified LLR LLR_M. The first ECC decoder 1241b may perform the first decoding operation by using the modified LLR LLR_M and generate the LLRs corresponding to the i-th iteration of the first decoding operation. The first ECC decoder 1241b may determine the sign data included in the LLRs corresponding to the i-th iteration of the first decoding operation as hard decision data corresponding to the i-th iteration, if the syndrome data for the hard decision data corresponding to the i-th iteration satisfies the constraints of the parity check matrix, may output the hard decision data corresponding to the i-th iteration as a decoded codeword DECODED CODEWORD.

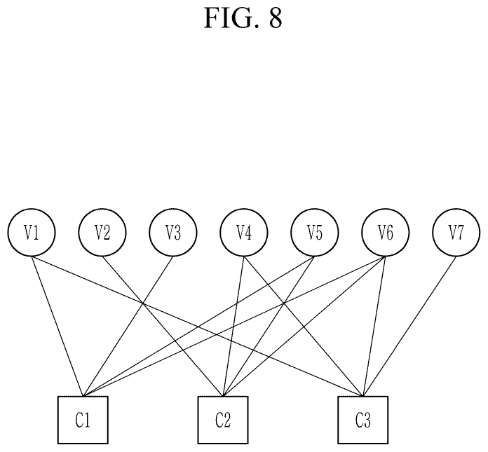

FIG. 8 is a view showing a Tanner graph to explain a first decoding operation and a second decoding operation according to an embodiment.

Referring to FIG. 8, the first ECC decoder and the second ECC decoder may include a plurality of variable nodes V1 to V7 and a plurality of check nodes C1 to C3. FIG. 8 shows seven variable nodes and three check nodes as an example. The solid line connected between the plurality of variable nodes V1 to V7 and the plurality of check nodes C1 to C3 represents an edge.

The first ECC decoder 1241b and the second ECC decoder 1242b may repeat the first decoding operation and the second decoding operation to modify the initial LLRs by exchanging messages between the plurality of variable nodes V1 to V7 and the plurality of check nodes C1 to C3.

In an embodiment, the first ECC decoder 1241b stores the initial LLRs in the plurality of variable nodes V1 to V7 and the plurality of check nodes C1 to C3. In an embodiment, the second ECC decoder 1242b stores the first initial LLRs corresponding to the first message data among the initial LLRs in the plurality of variable nodes V1 to V7 and the plurality of check nodes C1 to C3. Each of the initial LLRs may include a plurality of initial sign data and a plurality of initial reliability data.

In an embodiment, the LLRs stored in the first variable node V1, the third variable node V3, the fifth variable node V5, and the sixth variable node V6 are transmitted to the first check node C1. The first check node C1 may modify the LLRs received from the first variable node V1, the third variable node V3, the fifth variable node V5, and the sixth variable node V6 to generate first modified LLRs, and transmit the first modified LLRs to the first variable node V1, the third variable node V3, the fifth variable node V5, and the sixth variable node V6.

In an embodiment, the LLRs stored in the second variable node V2, the fourth variable node V4, and the sixth variable node V6 are transmitted to the second check node C2. The second check node C2 may modify the LLRs received from the second variable node V2, the fourth variable node V4, and the sixth variable node V6 to generate second modified LLRs, and transmit the second modified LLRs to the second variable node V2, the fourth variable node V4, and the sixth variable node V6.

In an embodiment, the LLRs stored in the first variable node V1, the fourth variable node V4, and the seventh variable node V7 may be transmitted to the third check node C3. The third check node C3 may modify the LLRs received from the first variable node V1, the fourth variable node V4, and the seventh variable node V7 to generate third modified LLRs, and transmit the third modified LLRs to the first variable node V1, the fourth variable node V4, and the seventh variable node V7.

In an embodiment, the LLRs stored in the first check node C1 and the third check node C3 may be transmitted to first variable node V1. The first variable node V1 may modify the LLRs received from the first check node C1 and the third check node C3, and forward the modified LLRs to the first check node C1 and the third check node C3.

In an embodiment, the second variable node V2 may modify the LLRs received from the second check node C2 and transmit the modified LLRs to the second check node C2. In an embodiment, the third variable node V3 may modify the LLRs received from the first check node C1 and transmit the modified LLRs to the first check node C1. The fourth variable node V4 may modify the LLRs received from the second check node C2 and the third check node C3 and transmit the modified LLRs to the second check node C2 and the third check node C3. The fifth variable node V5 may modify the LLRs received from the first check node C1 and the second check node C2 and transmit the modified LLRs to the first check node C1 and the second check node C2. The sixth variable node V6 may modify the LLRs received from the first check node C1, the second check node C2, and the third check node C3, and forward the modified LLRs to the first check node C1, the second check node C2, and the third check node C3 . . . . The seventh variable node V7 may modify the LLRs received from the third check node C3 and transmit the modified LLRs to the third check node C3.

In an embodiment, while the first decoding operation and the second decoding operation are repeated once, the plurality of variable nodes V1 to V7 may modify the LLRs received from the plurality of check nodes C1 to C3, and the plurality of check nodes C1 to C3 may modify the LLRs received from the plurality of variable nodes V1 to V7.

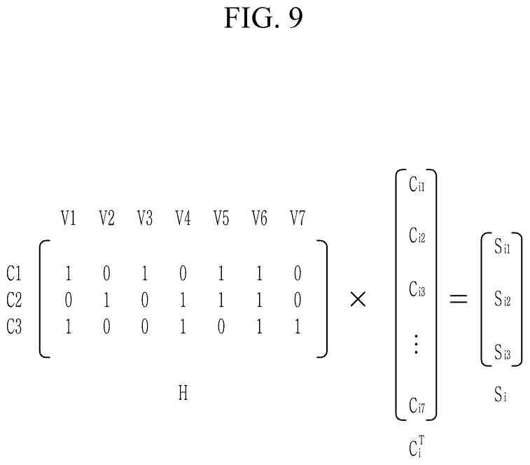

FIG. 9 is a view showing a parity check matrix to explain a first decoding operation and a second decoding operation according to an embodiment.

Referring to FIG. 9, a plurality of variable nodes V1 to V7 may correspond to columns of a parity check matrix H, and a plurality of check nodes C1 to C3 may correspond to rows of the parity check matrix H. Each of the entries included in the parity check matrix H may have a value of “1” if the connection between the variable node and the check node exists, and a value of “0” if there is no connection.

In an embodiment, the first ECC decoder 1241b determines the sign data included in the LLRs stored in the plurality of variable nodes V1 to V7 as the hard decision data corresponding to the i-th iteration in the i-th iteration of the first decoding operation. The first ECC decoder 1241b may generate a syndrome data Si corresponding to the i-th iteration based on the parity check matrix H and a transpose Cᵢ^{T} of the hard decision data Ci corresponding to the i-th iteration.

In an embodiment, if all entries included in the syndrome data Si corresponding to the i-th iteration are “0”, this means that the hard decision data Ci corresponding to the i-th iteration does not include error bits. The first ECC decoder 1241b may output the hard decision data Ci corresponding to the i-th iteration as a decoded codeword.

In an embodiment, if all entries included in the syndrome data Si corresponding to the i-th iteration are not “0”, this may mean that the hard decision data Ci corresponding to the i-th iteration includes error bits. The first ECC decoder 1241b may repeat the first decoding operation by the (i+1)-th time within the maximum number of repetitions.

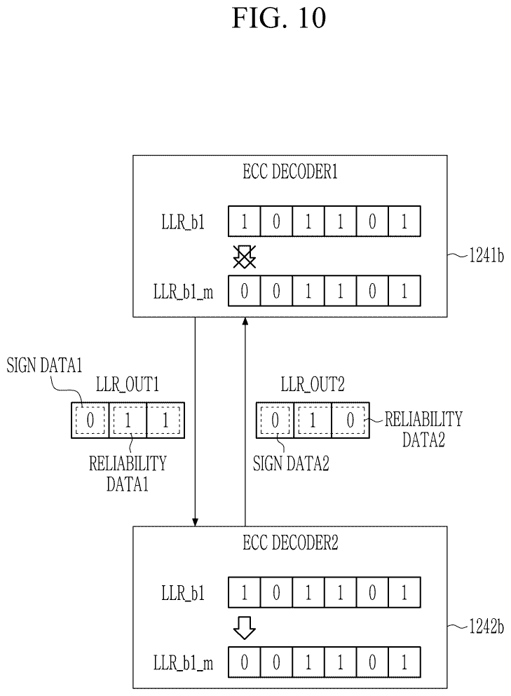

FIG. 10 is a view to explain a first output LLR and a second output LLR output by a first error correction code (ECC) decoder and a second ECC decoder according to an embodiment.

In FIG. 10, the first ECC decoder 1241b and the second ECC decoder 1242b, which modify the LLR LLR_b1 corresponding to the first bit included in the first message data, will be explained as an example.

Referring to FIG. 10, the first ECC decoder 1241b may generate the first output LLR LLR_OUT1 based on the LLRs corresponding to the i-th iteration of the first decoding operation. In an embodiment, the first output LLR LLR_OUT1 (e.g., three bits) includes first sign data SIGN DATA1 and a first reliability data RELIABILITY DATA1 indicating the size of the reliability of the first sign data SIGN DATA1. One bit of the first output LLR SIGN DATA1 may indicate the sign, and two bits may indicate the size of the reliability of the sign. The first ECC decoder 1241b may provide the first output LLR LLR_OUT1 to the second ECC decoder 1242b.

In an embodiment, the second ECC decoder 1242b receives the first output LLR LLR_OUT1 and modifies the LLR LLR_b1 corresponding to the first bit based on the first sign data SIGN DATA1 and the first reliability data RELIABILITY DATA1 included in the first output LLR LLR_OUT1. In an embodiment, the second ECC decoder 1242b modifies the sign data included in the LLR LLR_b1 corresponding to the first bit from “1” to “0” based on the first output LLR LLR_OUT1. The second ECC decoder 1242b may perform the second decoding operation based on the modified LLR LLR_b1_m corresponding to the first bit.

In an embodiment, the second ECC decoder 1242b generates a second output LLR LLR_OUT2 based on the LLRs corresponding to the k-th iteration of the second decoding operation. In an embodiment, the second output LLR LLR_OUT2 (e.g., 3 bits) includes a second sign data SIGN DATA2 and a second reliability data RELIABILITY DATA2 indicating the size of the reliability of the second sign data. One bit of the second output LLR LLR_OUT2 may indicate the sign, and two bits may indicate the size of the reliability of the sign. The second ECC decoder 1242b may provide the second output LLR LLR_OUT2 to the first ECC decoder 1241b.

In the embodiment, the first ECC decoder 1241b modifies the sign data included in the LLR LLR_b1 corresponding to the first bit data based on the size of the reliability of the second sign data SIGN DATA2 indicated by the second reliability data RELIABILITY DATA2 included in the second output LLR LLR_OUT2 as the second sign data SIGN DATA2.

In an embodiment, since the second reliability data RELIABILITY DATA2 is expressed in two bits and the reliability data of the LLR LLR_b1 corresponding to the first bit is expressed in five bits, the range that may indicate the size of the reliability of the second sign data SIGN DATA2 may be smaller than the range that may indicate the size of the reliability of the sign data of the LLR LLR_b1 corresponding to the first bit. In an embodiment, since the size range of the reliability of the second sign data SIGN DATA2 is smaller than the size range of the reliability of the sign data of the LLR LLR_b1 corresponding to the first bit, the size of the reliability of the second sign data SIGN DATA2 indicated by the second reliability data RELIABILITY DATA2 may be smaller than the size of the reliability of the sign data of the LLR LLR_b1 corresponding to the first bit indicated by the reliability data of the LLR LLR_b1 corresponding to the first bit. In an embodiment, since the size of the reliability of the second sign data SIGN DATA2 indicated by the second reliability data RELIABILITY DATA2 is smaller than the size of the reliability of the sign data of the LLR LLR_b1 corresponding to the first bit indicated by the reliability data of the LLR LLR_b1 corresponding to the first bit, a situation may occur in which the first ECC decoder 1241b does not modify the LLR LLR_b1 corresponding to the first bit according to the second sign data SIGN DATA2 included in the second output LLR LLR_OUT2. For example, since the reliability data value of the LLR LLR_b1 corresponding to the first bit indicates “01101” and the value of the reliability data RELIABILITY DATA2 of the second sign data SIGN DATA2 indicates “10”, the reliability size of the second sign data SIGN DATA2 is smaller than the reliability size of the LLR LLR_b1 corresponding to the first bit, and then the first ECC decoder 1241b does not modify the LLR LLR_b1 corresponding to the first bit. In another embodiment, even when the first ECC decoder 1241b modifies the LLR LLR_b1 corresponding to the first bit based on the size of reliability of the second sign data SIGN DATA2, since the size range of the reliability of the second sign data SIGN DATA2 indicated by the second reliability data RELIABILITY DATA2 is small, the range for modifying the LLR LLR_b1 corresponding to the first bit may be small. If the range for modifying the LLR LLR_b1 corresponding to the first bit of the first ECC decoder 1241b is small, the sign data of the LLR LLR_b1 corresponding to the first bit may still be an error bit, and the first decoding operation may still fail.

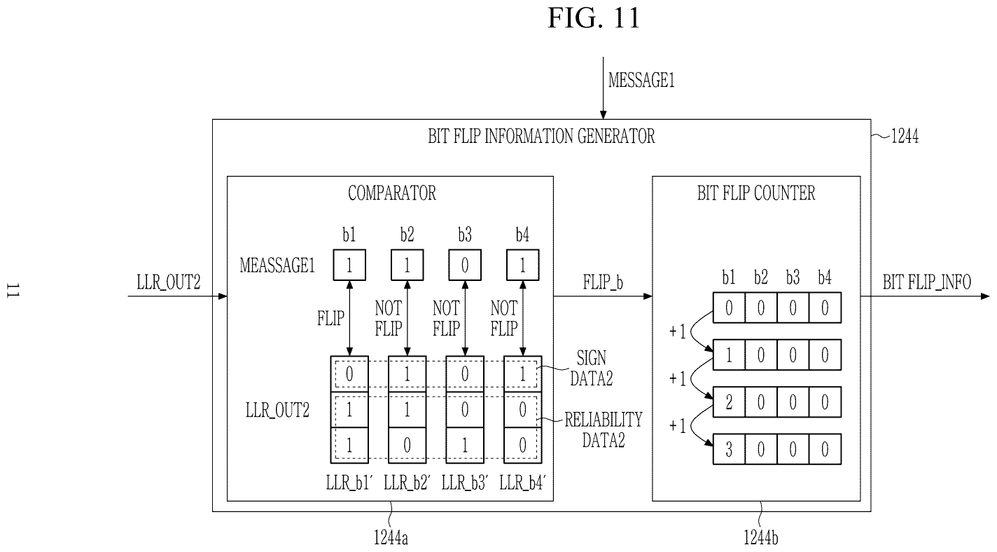

FIG. 11 is a view to explain a bit flip information generator that generates bit flip information according to an embodiment.

Referring to FIG. 11, the bit flip information generator 1244 may receive the first message data MESSAGE1 included in the codeword from LLR generator 1243. The bit flip information generator 1244 may receive the second output LLR LLR_OUT2 from the second ECC decoder 1242b. In an embodiment, the second output LLR LLR_OUT2 includes LLRs LLR_b1′ to LLR_b4′ respectively corresponding to the first to fourth bit data included in the first message data.

In an embodiment, the bit flip information generator 1244 includes a comparator 1244a and a bit flip counter 1244b. The comparator 1244a may compare the first to fourth bits b1 to b4 included in the first message data and the second sign data SIGN DATA2 included in the second output LLR LLR_OUT2. The comparator 1244a may provide information FLIP_b about the bit data having a different value from the second sign data SIGN DATA2 among the first to fourth bits b1 to b4 to the bit flip counter 1244b.

In an embodiment, the first bit b1 may be “1”, and the second sign data included in the LLR LLR_b1′ corresponding to the first bit may be “0”. The fact that the second sign data included in the LLR LLR_b1′ corresponding to the first bit is “0” may mean that the second sign data flipped from “1” to “0” by the second decoding operation.

In the embodiment, if the second to fourth bits b2 to b4 and the second sign data included in the LLRs LLR_b2′ to LLR_b4′ corresponding to the second to fourth bits are the same, it may mean that the second sign data was not flipped by the second decoding operation.

In an embodiment, the comparator 1244a may provide information FLIP_b regarding the bit data indicating that the bit data with a different value from the second sign data SIGN DATA2 among the first to fourth bits b1 to b4 is the first bit b1 to the bit flip counter 1244b.

The bit flip counter 1244b may count the number of times that the first to fourth bits b1 to b4 and the second sign data SIGN DATA2 included in the second output LLR LLR_OUT2 are determined to be different values. In an embodiment, the bit flip counter 1244b may increase the count number for the first bit by “1” if the first bit b1 in the k-th iteration of the second decoding operation has a different value from the second sign data included in the LLR LLR_b1′ corresponding to the first bit.

In an embodiment, the bit flip counter 1244b may increase the count number for the first bit by “1” if the first bit b1 in the (k+1)-th iteration of the second decoding operation has a different value from the second sign data included in the LLR LLR_b1′ corresponding to the first bit.

In an embodiment, the bit flip counter 1244b may generate bit flip information BIT FLIP_INFO indicating the number of times that the first to fourth bits b1 to b4 included in the first message data MESSAGE1 are determined to be a different value from the second sign data SIGN DATA2, and provide the bit flip information BIT FLIP_INFO to the message regenerator 1245. The bit flip information BIT FLIP_INFO may be information indicating the number of times that bits included in the first message data MESSAGE1 are flipped to the bits of the plurality of second sign data SIGN DATA2 included in the second output LLRs LLR_OUT2.

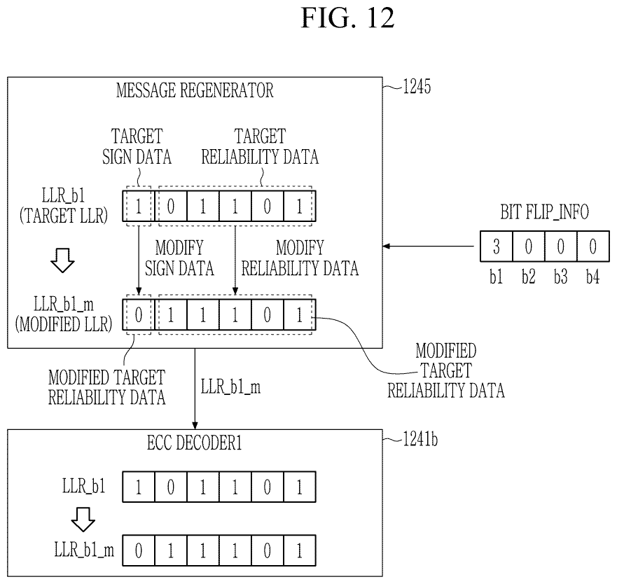

FIG. 12 is a view to explain a message regenerator that modifies a target LLR based on a bit flip information according to an embodiment.

Referring to FIG. 12, the message regenerator 1245 may receive the bit flip information BIT FLIP_INFO from the bit flip information generator 1244. The message regenerator 1245 may determine the target LLR TARGET LLR among the first initial LLRs corresponding to the first message data based on the bit flip information BIT FLIP_INFO. The target LLR TARGET LLR may include target sign data TARGET SIGN DATA and target reliability data TARGET RELIABILITY DATA. In an embodiment, the message regenerator 1245 determines the target sign data TARGET SIGN DATA among the plurality of first initial sign data included in the first initial LLRs based on the bit flip information BIT FLIP_INFO.

In an embodiment, the message regenerator 1245 may determine the LLR LLR_b1 of the first bit corresponding to the count number greater than a predetermined number among the count times for the first to fourth bits b1 to b4 included in bit flip information BIT FLIP_INFO as the target LLR TARGET LLR.

In an embodiment, the message regenerator 1245 modifies the target sign data TARGET SIGN DATA and the target reliability data TARGET RELIABILITY DATA included in the target LLR TARGET LLR based on the size of the reliability of the target sign data indicated by the target reliability data TARGET RELIABILITY DATA included in the bit flip information BIT FLIP_INFO and the target LLR TARGET LLR.

In an embodiment, if the count number for the first bit b1 included in the bit flip information BIT FLIP_INFO is greater than the predetermined number, and the size of the reliability of the target sign data is greater than the predetermined size, there may be a high possibility that the bit value of the target sign data TARGET SIGN DATA is an error bit. In an embodiment, the message regenerator 1245, if the count number for the first bit b1 included in the bit flip information BIT FLIP_INFO is greater than the predetermined number, and the size of the reliability of the target sign data is greater than the predetermined size, may modify the target sign data TARGET SIGN DATA and the target reliability data TARGET RELIABILITY DATA included in the target LLR TARGET LLR.

In an embodiment, the message regenerator 1245 generates a modified LLR MODIFIED LLR including a modified target sign data MODIFIED TARGET SIGN DATA and a modified target reliability data MODIFIED TARGET RELIABILITY DATA based on the bit flip information BIT FLIP_INFO and the size of the reliability of the target sign data. The message regenerator 1245 may determine the size of the reliability of the modified target sign data based on the bit flip information BIT FLIP_INFO and the size of the reliability of the target sign data, and generate a modified target reliability data MODIFIED TARGET RELIABILITY DATA based on the size of the reliability of the modified target sign data.

In an embodiment, the modified LLR MODIFIED LLR may include a modified target sign data MODIFIED TARGET SIGN DATA and a modified target reliability data MODIFIED TARGET RELIABILITY DATA expressed by six bits. One bit of the modified LLR MODIFIED LLR may indicate the modified target sign, and five bits of the modified LLR MODIFIED LLR may indicate the size of the reliability of the modified target sign. The number of the bits of the modified LLR MODIFIED LLR may be more than the number of the bits of the first output LLR LLR_OUT1 and the second output LLR LLR_OUT2 output by the first ECC decoder 1241b and the second ECC decoder 1242b of FIG. 10. The number of the bits of the modified target reliability data MODIFIED TARGET RELIABILITY DATA of the modified LLR MODIFIED LLR may be greater than the number of the bits of the first reliability data RELIABILITY DATA1 of the first output LLR LLR_OUT1. The number of the bits of modified target reliability data MODIFIED TARGET RELIABILITY DATA may be greater than the number of the bits of the second reliability data RELIABILITY DATA2 of second output LLR LLR_OUT2. The message regenerator 1245 may provide the modified LLR MODIFIED LLR including the modified target reliability data MODIFIED TARGET RELIABILITY DATA representing the reliability of the larger size than the first reliability data RELIABILITY DATA1 and the second reliability data RELIABILITY DATA2 to the first ECC decoder 1242b.

In an embodiment, the message regenerator 1245 modifies the LLR LLR_b1 corresponding to the first bit and provides the modified LLR LLR_b1_m corresponding to the first bit to the first ECC decoder 1242b.

In an embodiment, the first ECC decoder 1242b modifies the LLR LLR_b1 corresponding to the first bit based on the modified LLR LLR_b1_m corresponding to the first bit received from the message regenerator 1245. The first ECC decoder 1242b may change the LLR LLR_b1 corresponding to the first bit into the modified LLR LLR_b1_m corresponding to the first bit based on the result of comparing the size of the reliability of the target sign data indicated by the target reliability data TARGET RELIABILITY DATA included in the LLR LLR_b1 corresponding to the first bit and the size of the reliability of the modified target sign data indicated by the modified target reliability data MODIFIED TARGET RELIABILITY DATA.

The first ECC decoder 1242b may perform the first decoding operation based on the modified LLR LLR_b1_m and generate a modified first LLRs including a plurality of modified sign data and a plurality of modified reliability data corresponding to the first message data.

In an embodiment, the message regenerator 1245 only modifies the target reliability data TARGET RELIABILITY DATA without modifying the target sign data included in target LLR TARGET LLR, based on the size of the reliability of the target sign data indicated by the target reliability data TARGET RELIABILITY DATA included in the bit flip information BIT FLIP_INFO and the target LLR TARGET LLR. In an embodiment, the message regenerator 1245 modifies the target reliability data TARGET RELIABILITY DATA into data indicating the reliability of the size smaller than the predetermined size of the target sign data if the reliability size of the target sign data indicated by the target reliability data TARGET RELIABILITY DATA is greater than the predetermined size. In an embodiment, the message regenerator 1245 provides the modified LLR including the target sign data and the modified target reliability data to the first ECC decoder 1241b.

The first ECC decoder 1241b may perform the first decoding operation based on the modified LLR including the target sign data and the modified target reliability data. Since the size of the reliability of the target sign data has been lowered, the first ECC decoder 1241b may change the bit value of the target sign data while performing the first decoding operation.

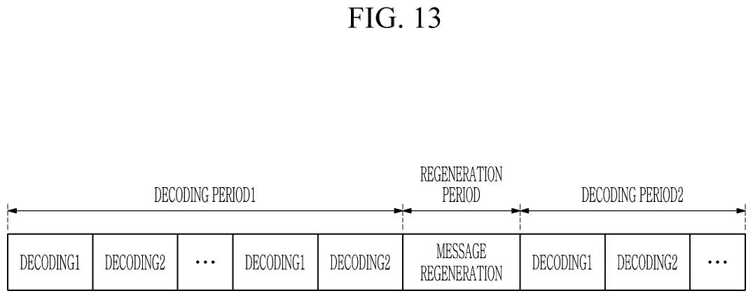

FIG. 13 is a view to explain an error correction circuit that generates a modified LLR based on the number of repetitions of a first decoding operation and a second decoding operation according to an embodiment.

Referring to FIG. 13, the first ECC decoder 1241b and the second ECC decoder 1242b may repeat the first decoding operation DECODING1 and the second decoding operation DECODING2 in a first decoding period DECODING PERIOD1. In an embodiment, two repetitions of the first decoding operation DECODING1 and one repetition of the second decoding operation DECODING2 may be performed sequentially in the first decoding period DECODING PERIOD1.

In a regeneration period REGENERATION PERIOD following the first decoding period DECODING PERIOD1, the message regenerator 1245 may generate the modified LLR based on the number of times that the first decoding operation DECODING1 and the second decoding operation DECODING2 are repeated. In an embodiment, if the number of times that the first decoding operation DECODING1 and the second decoding operation DECODING2 are repeated is more than a predetermined number, the message regenerator 1245 may modify the target sign data and the target reliability data included in the target LLR, and generate the modified LLR including the modified target sign data and the modified target reliability data.

In a second decoding period DECODING PERIOD2 following the regeneration period REGENERATION PERIOD, the first ECC decoder 1241b may perform the first decoding operation DECODING1 by using the modified LLR, and the second ECC decoder 1242b may perform the second decoding operation DECODING2 based on the first output LLR received from the first ECC decoder 1241b.

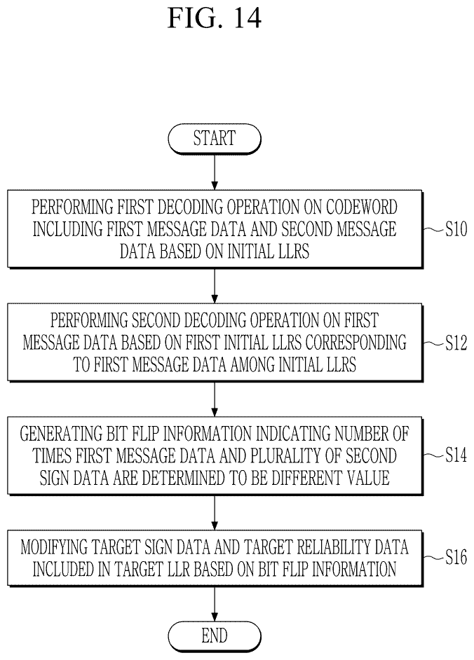

FIG. 14 is a flowchart to explain an error correction circuit that generates a modified LLR based on bit flip information according to an embodiment.

Referring to FIG. 14, in a step (S10), the first ECC decoder 1241b performs a first decoding operation on a codeword including first message data and second message data based on initial LLRs. The initial LLRs may include a plurality of initial sign data and a plurality of initial reliability data. The first ECC decoder 1241b may generate first output LLRs corresponding to the first message data. The first output LLRs may include a plurality of first sign data and a plurality of first reliability data.

In a step (S12), the second ECC decoder 1242b performs a second decoding operation on the first message data based on the first LLRs corresponding to the first message data among the initial LLRs. The first LLRs may include a plurality of first initial sign data and a plurality of first initial reliability data. The second ECC decoder 1242b may generate second output LLRs corresponding to the first message data. The second output LLRs may include a plurality of second sign data and a plurality of second reliability data.

In a step (S14), the bit flip information generator 1244 generates bit flip information indicating the number of times that the first message data and the plurality of second sign data are determined to be different values.

In a step (S16), the message regenerator 1245 modifies the target sign data included in the target LLR among the first LLRs and the target reliability data corresponding to the target sign data based on the bit flip information. The message regenerator 1245 may generate the modified LLR including the modified target sign data and the modified target reliability data.

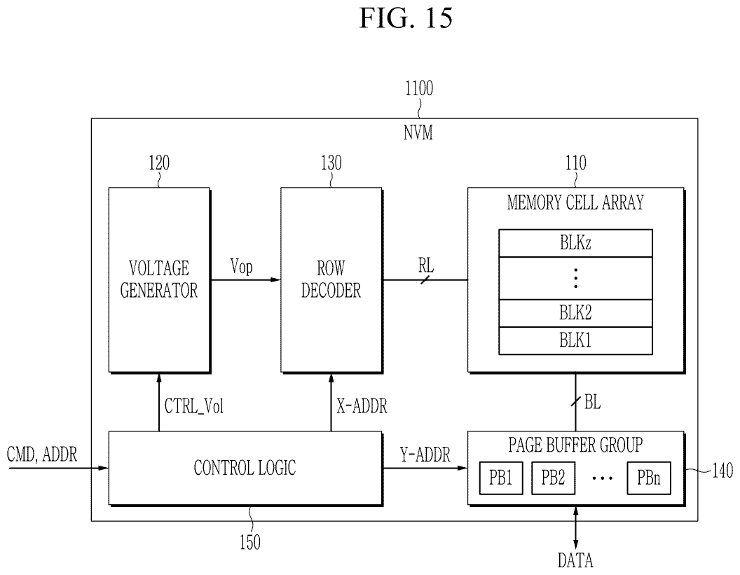

FIG. 15 is a view to explain a non-volatile memory device according to an embodiment.

Referring to FIG. 15, a non-volatile memory device 1100 may include a memory cell array 110, a voltage generator 120, a row decoder 130, a page buffer group 140, and a control logic 150.

The memory cell array 110 may include a plurality of memory blocks BLK1 to BLKz. The plurality of memory blocks BLK1 to BLKz may be connected to the row decoder 130 through row lines RL. The plurality of memory blocks BLK1 to BLKz may be connected to the page buffer group 140 through bit lines BL.

Each of the plurality of memory blocks BLK1 to BLKz may include a plurality of memory cells. In an embodiment, the plurality of memory cell may be non-volatile memory cells. In an embodiment, the plurality of memory cells may store codewords received from the storage controller.

The voltage generator 120 may generate operating voltages Vop by using an external power voltage supplied to the non-volatile memory device 1100. The voltage generator 120 may operate in response to the control of the control logic 150.

In an embodiment, the voltage generator 120 may generate operating voltages Vop used for the program operation, the read operation, and the erase operation. For example, the voltage generator 120 may generate an erase voltage, a program voltage, a pass voltage, a read voltage, and an erase voltage. The operating voltages Vop may be supplied to the memory cell array 110 by the row decoder 130.

The row decoder 130 may be connected to the memory cell array 110 through row lines RL. The row lines RL may include drain selection lines, word lines, and source selection lines.

The row decoder 130 may be configured to operate in response to the control of the control logic 150. The row decoder 130 may receive a row address X-ADDR from the control logic 150. In the embodiment, the row decoder 130 may select at least one word line among the plurality of word lines based on the row address X-ADDR, and apply operating voltages Vop provided from the voltage generator 120 to at least one word line.

In an embodiment, the row decoder 130 may apply a program voltage to a selected word line among the plurality of word lines and a pass voltage at a level lower than the program voltage to unselected word lines during a program operation. During a program verification operation, the row decoder 130 may apply a verification voltage to selected word lines and a verification pass voltage at a level higher than the verification voltage to unselected word lines.

During a read operation, the row decoder 130 may apply a read voltage to selected word lines and a read pass voltage at a level higher than the read voltage to unselected word lines.

The page buffer group 140 include a plurality of page buffers PB1 to PBn. The plurality of page buffers PB1 to PBn may each be connected to the memory cell array 110 through bit lines BL. The plurality of page buffers PB1 to PBn may be operated in response to the control of the control logic 150.

In an embodiment, the plurality of page buffers PB1 to PBn may receive data DATA from the outside. The plurality of page buffers PB1 to PBn may select at least one bit line among bit lines BL based on a column address Y-ADDR received from the control logic 150.

In an embodiment, the plurality of page buffers PB1 to PBn may transmit data received from the outside to the memory cells of the memory cell array 110 through the bit lines BL during the program operation. The memory cells may be programmed according to the data received. The plurality of page buffers PB1 to PBn may sense a data stored in the memory cells through the bit lines BL during the program verification operation.

During the read operation, the plurality of page buffers PB1 to PBn may sense the data stored in the memory cells through the bit lines BL and store the sensed data in the plurality of page buffers PB1 to PBn.

The control logic 150 may be connected to the voltage generator 120, the row decoder 130, and the page buffer group 140. The control logic 150 may be configured to control overall operations of the non-volatile memory device 1100. The control logic 150 may operate in response to commands CMD transmitted from the outside. The control logic 150 may control the voltage generator 120, the row decoder 130, and the page buffer group 140 by generating various signals in response to the command CMD and the address ADDR.

While this disclosure has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

What is claimed is:

1. An error correction circuit comprising:
a first error correction code (ECC) decoder configured to perform a first decoding operation on a codeword including first message data and second message data based on a plurality of initial sign data and a plurality of initial reliability data, and generate a plurality of first sign data corresponding to the first message data and a plurality of first reliability data corresponding to the plurality of first sign data;
a second ECC decoder configured to perform a second decoding operation on the first message data based on a plurality of first initial sign data corresponding to the first message data among the plurality of initial sign data and a plurality of first initial reliability data corresponding to the plurality of first initial sign data, and generate a plurality of second sign data corresponding to the first message data and a plurality of second reliability data corresponding to the plurality of second sign data;
a first logic circuit configured to generate bit flip information indicating a number of times that the first message data and the plurality of second sign data are determined to be different values for each bit; and
a second logic circuit configured to modify target sign data among the plurality of first initial sign data and target reliability data corresponding to the target sign data based on the bit flip information, and provide the modified target sign data and the modified target reliability data to the first ECC decoder.

2. The error correction circuit of claim 1, wherein:
the second logic circuit is configured to determine a size of the reliability of the modified target sign data based on the bit flip information and the size of the reliability of the target sign data indicated by the target reliability data, and modify the target reliability data based on the size of the reliability of the modified target sign data.

3. The error correction circuit of claim 2, wherein:
the second logic circuit is configured to modify the target sign data and the target reliability data when the number is greater than a predetermined number, and the size of the reliability of the target sign data indicated by the target reliability data is greater than a predetermined size.

4. The error correction circuit of claim 1, wherein:
the first ECC decoder is configured to perform the first decoding operation based on the modified target sign data and the modified target reliability data, and generate a plurality of first modified sign data corresponding to the first message data and a plurality of first modified reliability data corresponding to the plurality of first modified sign data.

5. The error correction circuit of claim 1, wherein:
the first ECC decoder is configured to provide the plurality of first sign data and the plurality of first reliability data to the second ECC decoder, and
the second ECC decoder is configured to generate the plurality of second sign data and the plurality of second reliability data based on the plurality of first sign data and the plurality of first reliability data.

6. The error correction circuit of claim 1, wherein:
the second ECC decoder is configured to provide the plurality of second sign data and the plurality of second reliability data to the first ECC decoder, and
the first ECC decoder is configured to modify the plurality of first sign data and the plurality of first reliability data based on the plurality of second sign data and the plurality of second reliability data.

7. The error correction circuit of claim 1, wherein:
the number of bits of the modified target reliability data is greater than the number of bits of the plurality of second reliability data.

8. The error correction circuit of claim 1, wherein:
the first logic circuit is configured to count the number of times that the first message data is changed to the plurality of second sign data based on a result of comparing the first message data and the plurality of second sign data.

9. The error correction circuit of claim 1, wherein:
the codeword includes first parity data generated based on the first message data and second parity data generated based on the first message data and the second message data.

10. The error correction circuit of claim 1, wherein:
the second logic circuit is configured to provide the modified target sign data and the modified target reliability data to the first ECC decoder based on the number of times that the first decoding operation and the second decoding operation are repeated.

11. The error correction circuit of claim 1, wherein:
the first ECC decoder is a low density parity check (LDPC) decoder, and
the second ECC decoder is a hamming decoder.

12. A storage controller comprising:
a memory interface configured to receive a codeword read from a non-volatile memory device;
a log likelihood ratio (LLR) generator configured to generate initial LLRs for first message data and second message data included in the codeword;
a first error correction code (ECC) decoder configured to perform a first decoding operation based on the initial LLRs to generate first output LLRs;
a second ECC decoder configured to perform a second decoding operation based on first initial LLRs corresponding to the first message data among the initial LLRs to generate second output LLRs;
a first logic circuit configured to generate bit flip information indicating a number of times that bits included in the first message data are flipped to bits of sign data included in the second output LLRs; and
a second logic circuit configured to determine a target LLR among the first LLRs based on the bit flip information, modify target sign data of the target LLR based on the bit flip information to generate a modified LLR, and provide the modified LLR to the first ECC decoder.

13. The storage controller of claim 12, wherein:
the second logic circuit is configured to modify target reliability data of the target LLR based on the bit flip information to further modify the LLR, and provide the further modified LLR to the first ECC decoder.

14. The storage controller of claim 13, wherein:
the second logic circuit is configured to determine a size of reliability of the modified target sign data based on the bit flip information and a size of reliability of the target sign data, and generate the modified target reliability data based on the size of the reliability of the modified target sign data.

15. The storage controller of claim 13, wherein:
the first ECC decoder is configured to change the target LLR to the modified LLR based on a result of comparing the target reliability data and the modified target reliability data.

16. The storage controller of claim 12, wherein:
a number of bits of each of the first output LLRs or the second output LLRs is less than a number of bits of the modified LLR.

17. A storage device comprising:
a non-volatile memory device configured to store a codeword including first message data, second message data, first parity data, and second parity data; and
a storage controller configured to perform a first decoding operation on the first message data and the second message data based on an initial log likelihood ratio (LLR), perform a second decoding operation on the first message data based on first initial LLRs corresponding to the first message data among initial LLRs, determine a target LLR among the initial LLRs based on a number of times that bit data included in the first message data is flipped to a different value by the second decoding operation, modify target sign data and target reliability data included in the target LLR based on the number of times, and perform the first decoding operation based on a modified target sign data and a modified target reliability data.

18. The storage device of claim 17, wherein the storage controller comprises:
a logic circuit configured to determine a size of a reliability of the modified target sign data based on a number of times that the target sign data is flipped by the second decoding operation, and generate the modified target reliability data based on the size of the reliability of the modified target sign data.

19. The storage device of claim 17, wherein the storage controller comprises:
a first ECC decoder configured to perform the first decoding operation by using a low density parity check (LDPC) code for generating a first output LLR; and
a second ECC decoder configured to perform the second decoding operation by using a hamming code for generating a second output LLR.

20. The storage device of claim 19, wherein:
a number of bits of reliability data included in the first output LLR or the second output LLR is less than a number of bits of the modified target reliability data.
